(19) United States
(12) Patent Application Publication
(10) Pub. No.: US 2008/0194104 A1
(43) Pub. Date: Aug. 14, 2008

(54) APPARATUS FOR PLASMA CHEMICAL VAPOR DEPOSITION AND METHOD FOR FABRICATING SEMICONDUCTOR DEVICE BY USING THE SAME

(75) Inventors: Dong-Sun Sheen, Ichon-shi (KR); Seok-Pyo Song, Ichon-shi (KR); Sang-Tae Ahn, Ichon-shi (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Ichon-shi (KR)

(21) Appl. No.: 12/106,155

(22) Filed: Apr. 18, 2008

Related U.S. Application Data
(62) Division of application No. 11/215,952, filed on Aug. 30, 2005.

(30) Foreign Application Priority Data
Oct. 28, 2004 (KR) 10-2004-0086878

(51) Int. Cl. H01L 21/44

(52) U.S. Cl. 438/680; 257/E21.17

(57) ABSTRACT

An apparatus for use in a plasma chemical vapor deposition (CVD) includes a chamber; a cooling gas inlet passing through an electrostatic chuck for supplying a cooling gas to the bottom surface of a wafer when the plasma CVD process is performed; and a clamping unit for clamping the wafer to the electrostatic chuck when the cooling gas is supplied.

### CROSS-REFERENCES TO RELATED APPLICATIONS

The present application claims priority to Korean Patent Application No. 10-2004-0086878, filed Oct. 28, 2004, which is incorporated by reference.

### BACKGROUND OF THE INVENTION

The present invention relates to a method for fabricating a semiconductor device; and, more particularly, to an apparatus for use in a plasma chemical vapor deposition method and a method for fabricating a semiconductor device by using the same.

### BRIEF SUMMARY OF THE INVENTION

In a highly integrated semiconductor device, a minimum line width (a spacing distance between fine patterns) has been decreasing. Thus, it is highly desirable to fill gaps formed between these fine patterns and planarize the gap-filled fine patterns thereafter. Also, a process subsequent to this planarization needs to be performed at low temperature to obtain an intended function of a fine metal-oxide-semiconductor field effect transistor (MOSFET) formed on a substrate and to prevent degradation of the MOSFET.

An insulation layer used for filling the gaps between the fine patterns is based on a material such as borophosphosilicate glass (BPSG), O₃-tetraethylorthosilicate undoped silicate glass (TEOS USG) or the like. However, BPSG requires a reflow process performed at high temperature more than 800° C. and is inappropriate to fill a small gap due to a high etched amount of the BPSG during a wet etching process. Also, since O₃-TEOS USG has a poor gap-fill property despite a low thermal budget, the O₃-TEOS USG cannot be applied for fabricating a highly scaled-down semiconductor device.

To solve this problem, a silicon dioxide (SiO₂) layer is currently employed as a gap-filling insulation layer along with use of a high density plasma chemical vapor deposition (HDP CVD) method. Such a silicon dioxide layer can be deposited at a low temperature ranging from 500° C. to approximately 700° C. and has good gap-fill properties. For these reasons, the silicon dioxide layer obtained through the HDP CVD method is widely used as the gap-filling insulation layer of the highly scaled-down semiconductor device.

FIG. 1 is a diagram showing a conventional apparatus for a HDP CVD method.

As shown, the HDP CVD apparatus includes: a chamber 100; a wafer 101 on which a silicon dioxide layer 150 is formed through a HDP CVD method; an electrostatic chuck 102 disposed beneath the wafer 101 for anchoring the wafer; a pair of source gas inlets 103 disposed at the bottom side of the chamber 100; a first radio frequency (RF) power supplier 104 for supplying RF power to generate a high density plasma within the chamber 100; an inductive coil 105 disposed outside the chamber 100; a vacuum pump 106 disposed at the bottom side of the chamber 100 for pumping byproducts out; a second RF power supplier 107 for supplying RF power to the electrostatic chuck 102 to attract ions and radicals of the high density plasma towards the wafer 101; and an oscillating antenna 108 for igniting the high density plasma passing through the center of the chamber 100.

However, the high density plasma containing charged particles like ions or electrons that are generated during the HDP CVD method for depositing the silicon dioxide layer 150 on the wafer 101 can penetrate into a silicon substrate or devices such as a gate insulation layer and MOSFETs formed on the silicon substrate through conductive wires connected to the substrate or devices. The penetration of the charged particles causes driving power and reliability of the devices to be degraded as well as results in defects due to erroneous operation. These adverse effects are referred as a phenomenon of plasma induced damage (PID) caused by the HDP CVD method.

Specifically, the PID phenomenon may cause other problems such as an increase in leakage current of a gate oxide layer of a MOSFET, fatigue, an increase in leakage current of a junction diode, an amplification of hot carrier damage, a short channel effect and so forth.

Also, the PID phenomenon becomes more severe in a highly integrated semiconductor device of which the minimum line width is below 100 nm due to the following reasons.

First, as the semiconductor device has been highly integrated, a channel length of the MOSFET becomes shortened, and thus, an electric field applied to the channel is increased. This increased electric field causes current of the channel to be leaked in greater extents. Second, as the gate oxide layer becomes thinner, a breakdown voltage of the gate oxide layer gets lowered due to increase in leakage current. Third, an electric field of the junction diode becomes stronger because a doping concentration of a well in the silicon substrate increases. As a result of the stronger electric field, an increase in junction leakage current is more likely to occur due to a thermal field emission (TFE) phenomenon that arises when electrons are discharged by thermal heating and a high electric field. Also, the number of hot electrons increases, leading to a decrease in the driving power of the MOSFET when used for a prolonged time.

With reference to drawings, these mentioned problems are explained hereinafter.

FIG. 2 is a graph showing a dielectric breakdown electric field (E_{BD}) distribution of an N-type MOS capacitor within a wafer when a conventional HDP CVD method is used for gap-filling between conductive wires. Especially, the distribution of the dielectric breakdown electric field (E_{BD}) shown in FIG. 2 is determined by leakage currents generated from a gate insulation layer in the N-type MOS capacitor formed on a silicon substrate.

In the N-type MOS capacitor fabricated by an interconnection method with the conventional HDP CVD process, the dielectric breakdown electric field becomes lowered at a partial portion of the wafer, and this lowered dielectric breakdown electric field indicates that the undesired leakage current of the N-type MOS capacitor increases.

FIG. 3 is a graph showing a dielectric breakdown electric field (E_{BD}) distribution of a P-type MOS capacitor within a wafer when a conventional HDP CVD method is used for gap-filling between conductive wires. As with the N-type MOS capacitor shown in FIG. 2, the P-type MOS capacitor fabricated through the conventional HDP CVD method has the dielectric breakdown electric field that is lowered at a partial portion of the wafer. This lowered dielectric breakdown electric field is associated with the increase of the leakage current of the P-type MOS capacitor, which is undesirable.

FIG. 4 is a graph showing a pass-rate of a dielectric breakdown electric field of a gate insulation layer in one of MOS capacitors formed on a silicon substrate by an interconnection method with a conventional HDP CVD process. As shown, the pass-rate of the dielectric breakdown electric field is dropped in some types of MOS capacitor test pattern.

FIG. 5 is a graph showing a leakage current distribution of a gate insulation layer when a predetermined voltage is applied to a gate electrode of a P-type MOSFET. Herein, the P-type MOSFET, including the gate insulation layer, is formed on a silicon substrate by an interconnection method along with the application of a conventional HDP CVD method. Especially, the illustrated leakage current distribution is based on an antenna ratio, which is defined as a ratio of the total area of a gate electrode and a conductive interconnection line connected with the gate electrode to the area of a gate insulation layer, more specifically, a gate oxide layer. The higher antenna ratio means a larger amount of plasma is directed toward the gate oxide layer during the application of the HDP CVD method.

FIG. 6 is a graph showing a distribution of a dielectric breakdown charge amount (Q_{BD}) within a wafer when a certain level of charges is applied to a gate insulation layer in an N-type MOS capacitor formed on a silicon substrate by an interconnection method with a conventional HDP CVD process. Especially, the dielectric breakdown charge amount is measured through a constant current stress test (CCST).

FIG. 7 is a graph showing a distribution of a saturation threshold voltage shift (ΔVtsat) caused by hot electrons injected into a conventionally fabricated MOSFET in a cell region. Especially, the illustrated saturation threshold voltage shift distribution shows a degradation degree of the MOSFET caused by the hot electron injection.

If the semiconductor device is degraded by the above described PID phenomenon, the yields of semiconductor devices may be reduced. Also, it makes it difficult to reduce the semiconductor device size, and may decrease reliability of the semiconductor device and increase defects.

Meanwhile, the high density plasma can also penetrate into conductive line patterns while forming an insulation layer (e.g., silicon dioxide) over the conductive line patterns using the HDP CVD process.

Accordingly, it is desirable to prevent the PID phenomenon while providing the gap-fill property during the HDP CVD process for the purpose of achieving high driving power and good reliability of highly integrated semiconductor devices.

The present invention relates to providing an apparatus that is used in a plasma chemical vapor deposition (CVD) method. In one embodiment, the apparatus is configured to present/reduce plasma induced damage while maintaining a gap-fill property during the application of the plasma CVD method.

In one embodiment of the present invention, a plasma chemical vapor deposition (CVD) apparatus comprises a chamber; a wafer receiver configured to receive and secure a bottom surface of a wafer to an electrostatic chuck; a cooling gas inlet passing through the electrostatic chuck for supplying a cooling gas to the bottom surface of the wafer when the plasma CVD process is performed; and a clamping unit for clamping the wafer to the electrostatic chuck when the cooling gas is supplied.

In another embodiment of the present invention, a method for fabricating a semiconductor device comprises forming a plurality of conductive lines on a wafer provided with various devices including transistors; anchoring the wafer to an electrostatic chuck of an apparatus for use in a plasma chemical vapor deposition (CVD) method; and depositing an insulation layer filling gaps each created between the conductive lines while cooling the wafer by spraying a cooling gas over a bottom surface of the wafer.

### BRIEF DESCRIPTION OF THE DRAWINGS

FIG. 1 is a configuration diagram showing a conventional apparatus for use in a high density plasma chemical vapor deposition (HDP CVD) method.

FIG. 2 is a graph showing a dielectric breakdown electric field distribution of an N-type metal-oxide-semiconductor (MOS) capacitor within a wafer, wherein the N-type MOS capacitor is fabricated using an interconnection technique with a conventional HDP CVD process.

FIG. 3 is a graph showing a dielectric breakdown electric field distribution of a P-type MOS capacitor within a wafer, wherein the P-type capacitor is fabricated using an interconnection method with a conventional HDP CVD process.

FIG. 4 is a graph showing a pass-rate of a dielectric breakdown electric field of a gate insulation layer in a MOS capacitor fabricated using an interconnection method with a conventional HDP CVD process.

FIG. 5 is a graph showing a leakage current distribution of a gate insulation layer when a predetermined voltage is applied to a gate electrode of a P-type metal-oxide-semiconductor field effect transistor (MOSFET) fabricated using an interconnection technique.

FIG. 6 is a graph showing a distribution of a dielectric breakdown charge amount within a wafer when a certain level of charges is applied to a gate insulation layer of an N-type MOS capacitor fabricated using an interconnection technique.

FIG. 7 is a graph showing a distribution of a saturation threshold voltage shift caused by hot electrons injected into a MOSFET in a cell region, wherein the MOSFET is fabricated using an interconnection technique.

FIGS. 8A and 8B are cross-sectional views illustrating a method for fabricating a semiconductor device in accordance with a preferred embodiment of the present invention.

FIG. 9 is a configuration diagram showing an apparatus for use in a plasma CVD method in accordance with the preferred embodiment of the present invention.

FIG. 10 is a graph showing a dielectric breakdown electric field distribution of an N-type MOS capacitor within a wafer according the preferred embodiment of the present invention.

FIG. 11 is a graph showing a dielectric breakdown electric field distribution of a P-type MOS capacitor within a wafer according the preferred embodiment of the present invention.

FIG. 12 is a graph showing a pass-rate of a dielectric breakdown electric field of a gate insulation layer of a MOS capacitor fabricated according to the preferred embodiment of the present invention.

FIG. 13 is a graph showing a distribution of leakage currents of a gate insulation layer of a P-type MOSFET fabricated according to the preferred embodiment of the present invention.

FIG. 14 is a graph showing a distribution of a dielectric breakdown charge amount within a wafer when a certain level of charges are applied to a gate insulation layer of an N-type MOS capacitor fabricated according to the preferred embodiment of the present invention.

FIG. 15 is a graph showing a distribution of a saturation threshold voltage shift caused by hot electrons injected into a MOSFET in a cell region according to the preferred embodiment of the present invention.

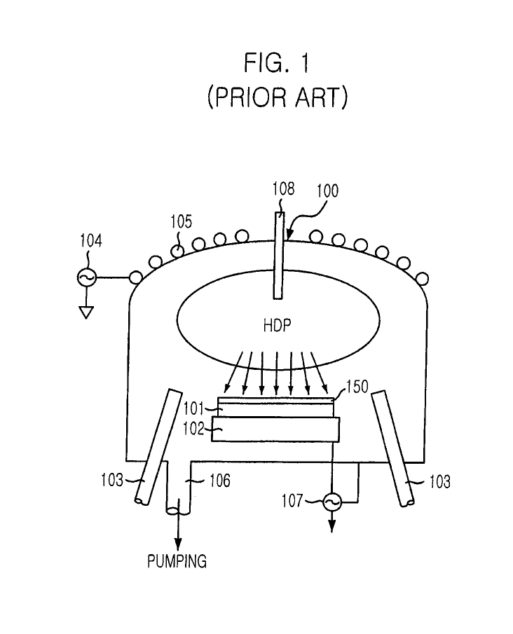

### DETAILED DESCRIPTION OF THE INVENTION

An apparatus for high density plasma chemical vapor deposition and a method for fabricating a semiconductor device by using the same in accordance with preferred embodiments of the present invention will be described in detail with reference to the accompanying drawings.

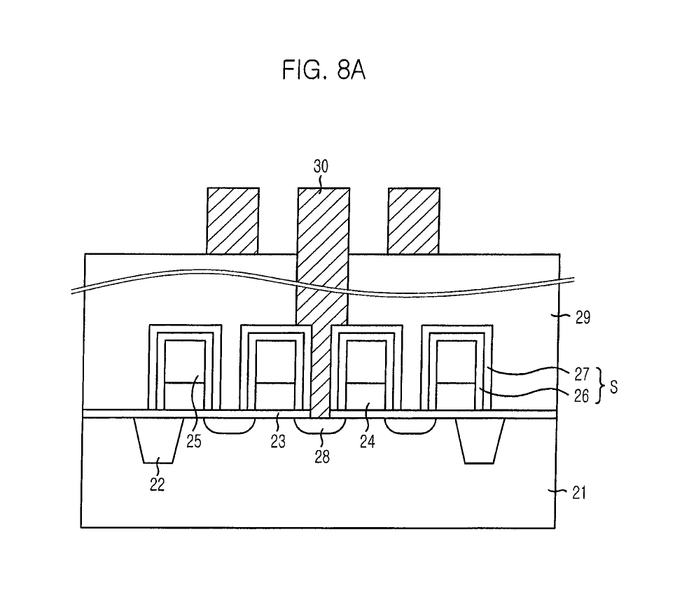

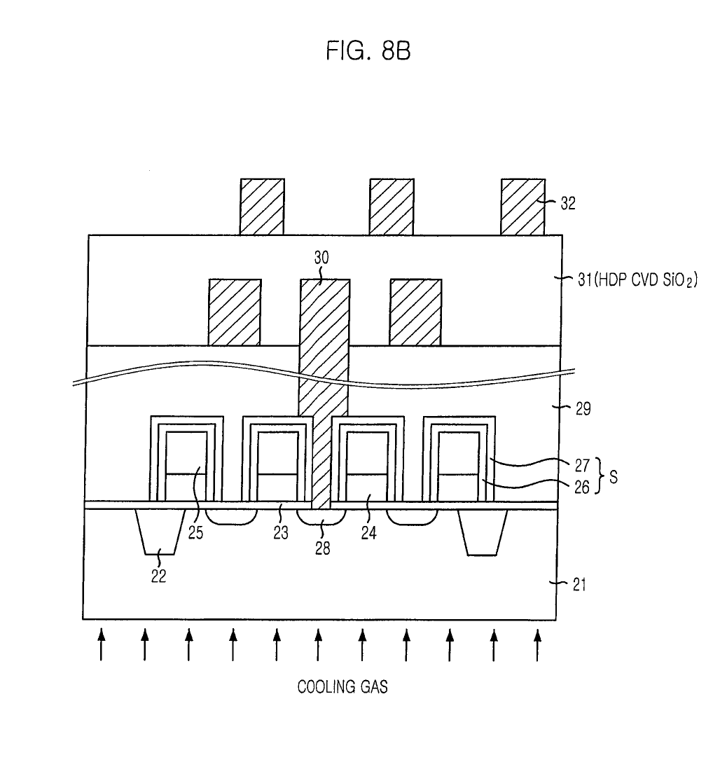

FIGS. 8A and 8B are cross-sectional views illustrating a method for fabricating a semiconductor device in accordance with a preferred embodiment of the present invention.

Referring to FIG. 8A, device isolation regions 22 are formed in a substrate 21 through a shallow-trench-isolation (STI) process, and a gate insulation layer 23 is then formed on the substrate 21. The substrate 21 is based on silicon in the present implementation. A plurality of gate structures each including a gate electrode 24 and a hard mask 25 are formed on the gate insulation layer 23. The gate electrode 24 is based on a single layer of polysilicon or stacked layers of polysilicon and tungsten. It is also possible to use tungsten silicide instead of tungsten. The hard mask 25 is formed by using silicon nitride.

Next, an oxide layer 26 and a nitride layer 27 are sequentially formed on the gate structures to form spacers S. Then, using the spacers S and the gate structures, an ion implantation process is performed to form a plurality of source/drain junctions 28 beneath a surface of the substrate 21 disposed between the gate structures.

Afterwards, an inter-layer insulation layer 29 is formed over the above resulting substrate structure, and then, although not illustrated, the inter-layer insulation layer 29 is etched to form a plurality of contact holes exposing the corresponding source/drain junctions 28 disposed between the gate structures. A plurality of first conductive lines 30 are formed and fill the contact holes.

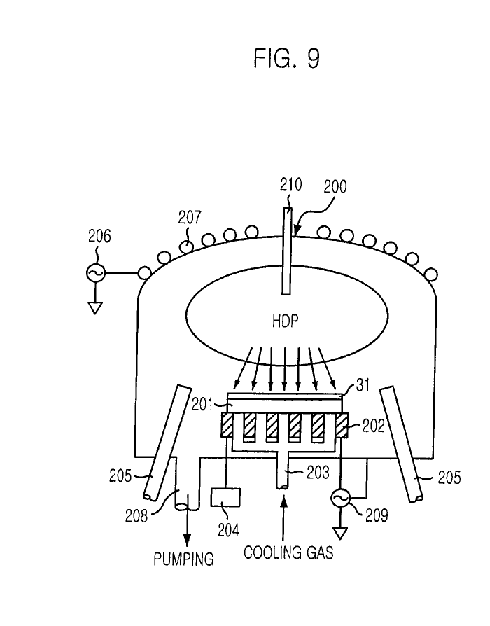

A wafer obtained from the above described sequential processes is clamped and placed on an electrostatic chuck of an apparatus for use in a plasma chemical vapor deposition (CVD) method. With reference to FIG. 9, specific configuration of the plasma CVD apparatus will be provided in the foregoing explanation. Also, it should be noted that the use of a high density plasma (HDP) is provided as an exemplary process in the foregoing explanation. Other types of plasma can be used.

Referring to FIG. 8B, while a cooling gas such as an inert gas is sprayed over a bottom surface of the substrate 21, a silicon dioxide (SiO₂) layer 31 is formed on an entire surface of the above resulting substrate structure through performing the HDP CVD method, thereby filling gaps created between the first conductive lines 30. Then, the silicon dioxide layer 31 is planarized by polishing a portion of the silicon dioxide layer 31 through a chemical vapor polishing (CMP) process. Subsequent to the planarization process, a process for forming a plurality of second conductive lines 32 on the planarized silicon dioxide layer 31 is performed.

As mentioned above, during the formation of the silicon dioxide layer 31 through the HDP CVD method, the cooling gas is sprayed over the bottom surface of the substrate structure, i.e., the wafer, for the purpose of cooling the wafer. Thus, it is possible to prevent/reduce charged particles of a high density plasma from penetrating into the above-described devices. As the penetration of the charged particles is reduced, it is further possible to prevent an incidence of plasma induced damage (PID).

FIG. 9 is a configuration diagram showing an apparatus for use in a HDP CVD method in accordance with the preferred embodiment of the present invention.

As shown, the HDP CVD apparatus includes: a chamber 200; a wafer 201 on which the silicon dioxide layer 31 is deposited through a HDP CVD method; an electrostatic chuck 202 disposed beneath the wafer 201 for anchoring the wafer 201; a cooling gas inlet 203 for supplying a cooling gas to the entire wafer 201 through the electrostatic chuck 202 during the application of the HDP CVD method; an electrostatic generator 204 extrinsically connected with the electrostatic chuck 202 for generating static electricity to clamp the wafer 201 when the cooling gas is supplied; a pair of source gas inlets 205 disposed at a bottom side of the chamber 200; a first radio frequency (RF) power supplier 206 for supplying RF power to generate a high density plasma (HDP) within the chamber 200; an inductive coil 207 disposed outside the chamber 200; a vacuum pump 208 disposed at the bottom side of the chamber 200 for pumping out byproducts; a second RF power supplier 209 for supplying RF power to the electrostatic chuck 202 to attract ions and radicals of the high density plasma towards the wafer 201; and an oscillating antenna 210 for igniting the high density plasma passing through the center of the chamber 200.

Particularly, the cooling gas inlet 203 has a number of tubes to supply the cooling gas evenly to the bottom side of the wafer 201, and these tubes penetrate the electrostatic chuck 202, reaching to the bottom side of the wafer 201. Also, although the electrostatic generator 204 is used as a device for clamping the wafer 201, it is still possible to use another clamping device such as a presser that mechanically presses both ends of the wafer 201 or a pump that causes a rear surface of the wafer 201 to be adhered onto the electrostatic chuck 202 by applying vacuum pumping to the rear surface of the wafer 201. These clamping devices prevent the wafer 201 from being shaken when the cooling gas is sprayed over the bottom surface of the wafer 201 and also prevent the cooling gas sprayed over the bottom surface of the wafer 201 from being leaked out to the entire wafer 201 and inside the chamber 200.

Hereinafter, a method for depositing the silicon dioxide layer 31 by employing the HDP CVD method along with use of the HDP CVD apparatus will be described in detail.

First, the wafer 201 is anchored at the electrostatic chuck 202 by using static electricity. Then, a source gas is supplied into the chamber 200 through the source gas inlets 205, and RF power is supplied to the inductive coil 207 to generate a high density plasma inside the chamber 200.

Next, the electrostatic chuck 202 is supplied with RF power, which is generally called bias power through the second RF power supplier 209, so that the high density plasma is attracted towards the wafer 201. As a result, the silicon dioxide layer 31 is deposited.

During the deposition of the silicon dioxide layer 31, an inert gas used as the cooling gas is sprayed over the bottom surface of the wafer 201 through the cooling gas inlet 203. The inert gas is selected from a group consisting of helium (He), hydrogen (H₂), nitrogen (N₂), argon (Ar) and neon (Ne). The inert gas is flowed at the rate of approximately 10 sccm to approximately 200 sccm. Also, a pressure at the bottom surface of the wafer 201 is set to be in a range from approximately 0.1 torr to approximately 50 torr. Under this specific condition, a temperature of the wafer 201 is set to range from approximately 100° C. to approximately 450° C.

As the amount of the inert gas sprayed over the bottom surface of the wafer 201 increases, the pressure at the bottom surface of the wafer 201 increases and the temperature of the wafer 201 decreases, thereby improving cooling efficiency. However, if the amount of the inert gas is too high, it is difficult to clamp the wafer 201 and the inert gas is leaked inside the chamber 200, affecting the HDP CVD process applied over the entire wafer 201. Also, the inert gas can be supplied for a predetermined period prior to a whole or partial period of depositing the silicon dioxide layer 31 or after the silicon layer 31 is deposited.

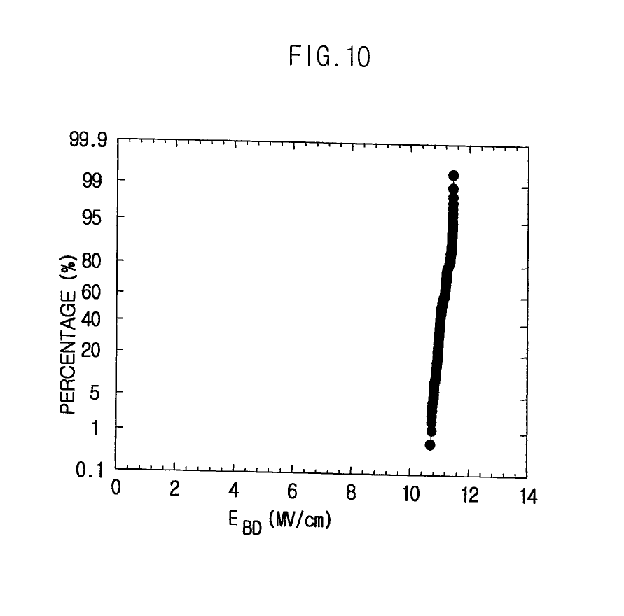

FIG. 10 is a graph showing a dielectric breakdown electric field distribution of an N-type metal-oxide-semiconductor (MOS) capacitor within a wafer according the preferred embodiment of the present invention. Especially, the dielectric breakdown electric field (E_{BD}) is dependent on leakage currents generated from a gate insulation layer of the N-type MOS capacitor formed on a silicon substrate.

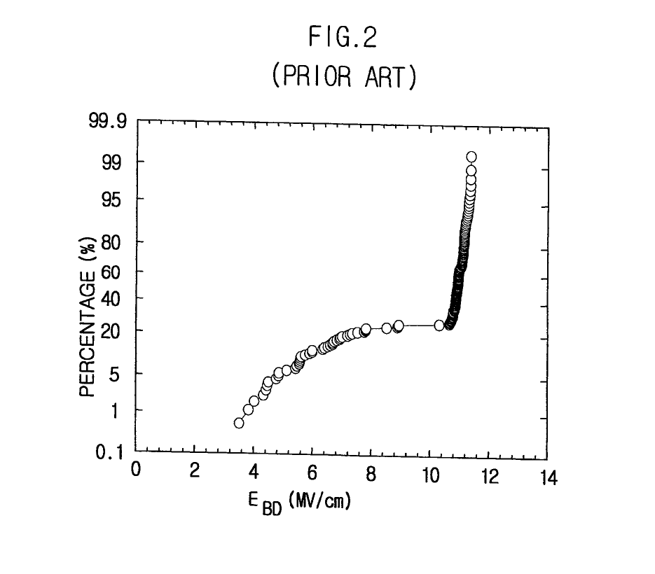

In the conventional N-type MOS capacitor shown in FIG. 2, the dielectric breakdown electric field becomes lowered at a given portion of the wafer, indicating the increase of the undesired leakage current of the N-type MOS capacitor. In comparison, as shown in FIG. 10, when a silicon dioxide layer is deposited using the HDP CVD method above, the dielectric breakdown electric field is less likely to decrease. That is, the dielectric breakdown electric field is uniformly distributed within the wafer and maintains high values.

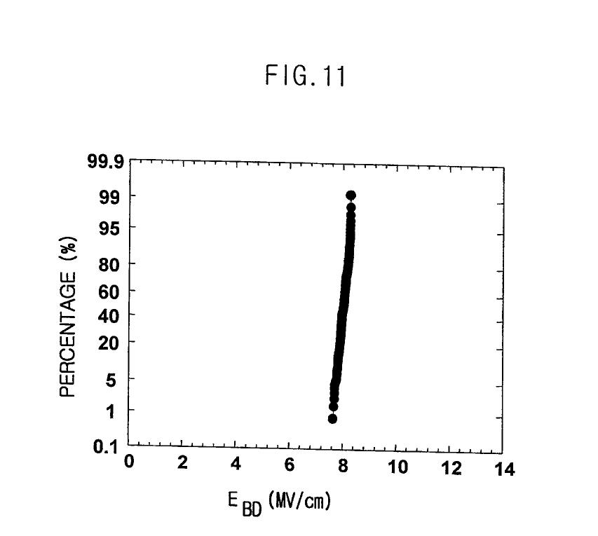

FIG. 11 is a graph showing a dielectric breakdown electric field distribution of a P-type MOS capacitor within a wafer according the preferred embodiment of the present invention. The dielectric breakdown electric field (E_{BD}) is caused by leakage currents generated from a gate insulation layer of the P-type MOS capacitor formed on a silicon substrate.

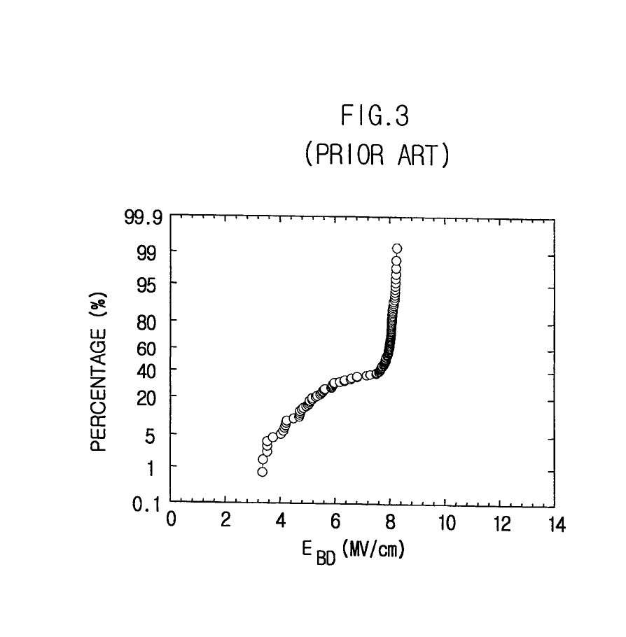

In comparison with the conventional P-type MOS capacitor (see FIG. 3), when a silicon dioxide layer is deposited through using the HDP CVD method above, the dielectric breakdown electric field is kept high, as shown in FIG. 11.

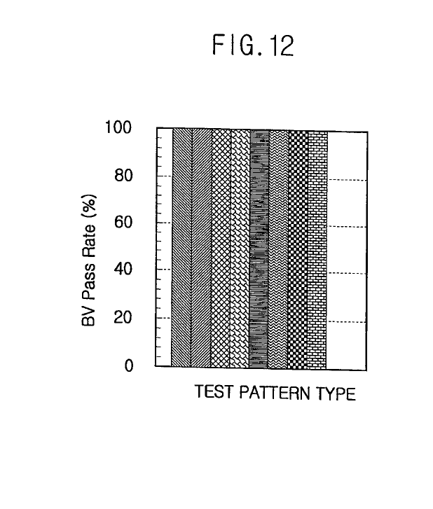

FIG. 12 is a graph showing a pass-rate of a dielectric breakdown electric field of a gate insulation layer in one of various MOS capacitors fabricated according to the preferred embodiment of the present invention.

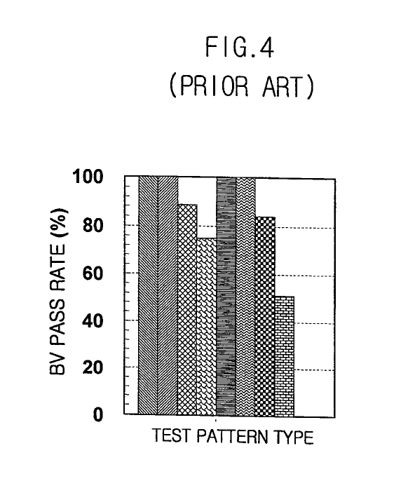

In comparison with FIG. 4, the deposition of a silicon dioxide layer using the HDP CVD method above leads to an increase in the average pass-rate of the MOS capacitor.

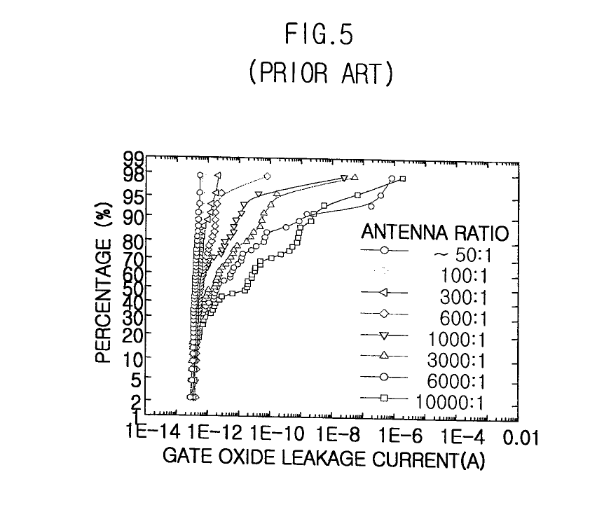

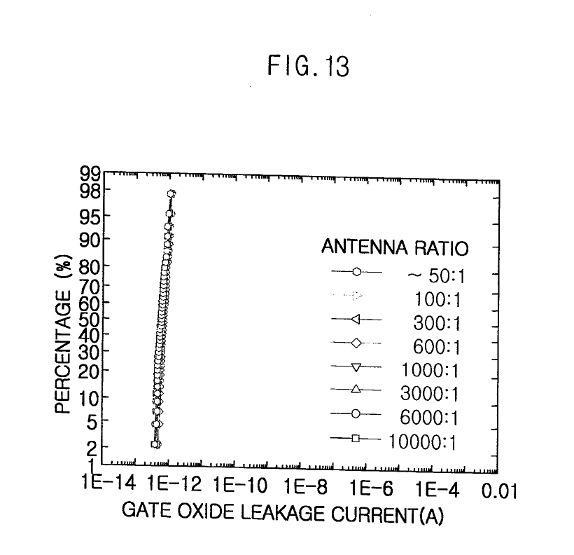

FIG. 13 is a graph showing a distribution of leakage currents of a gate insulation layer of a P-type metal-oxide-semiconductor field effect transistor (MOSFET) fabricated according to the preferred embodiment of the present invention. The illustrated the leakage current distribution of the gate insulation layer is based on an antenna ratio, and the leakage current measured as a predetermined voltage is applied to a gate electrode of the P-type MOSFET being formed on a silicon substrate. In comparison with FIG. 5, the leakage current of the P-type MOSFET does not increase as much as shown in FIG. 13 and is independent of the antenna ratios.

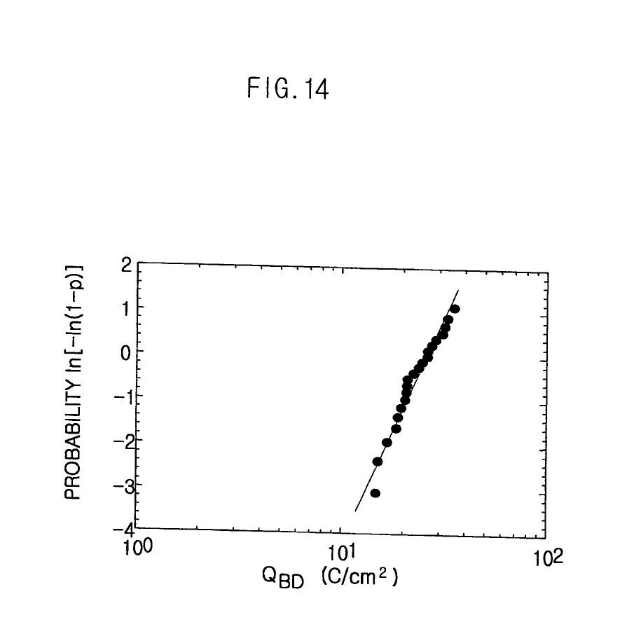

FIG. 14 is a graph showing a distribution of a dielectric breakdown charge amount (Q_{BD}) within a wafer when a certain level of charges are applied to a gate insulation layer of an N-type MOS capacitor fabricated according to the preferred embodiment of the present invention. The dielectric breakdown charge amount is measured through a constant current stress test (CCST).

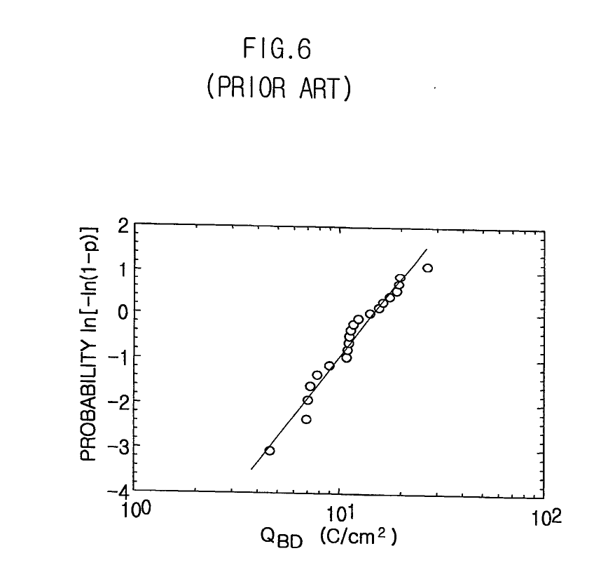

In comparison with the distribution of the dielectric breakdown charge amount in the convention N-type MOS capacitor shown in FIG. 6, reliability of the N-type MOS capacitor is improved, indicating that a lifetime of the MOS capacitor or MOSFET using a gate insulation layer is likely to be increased.

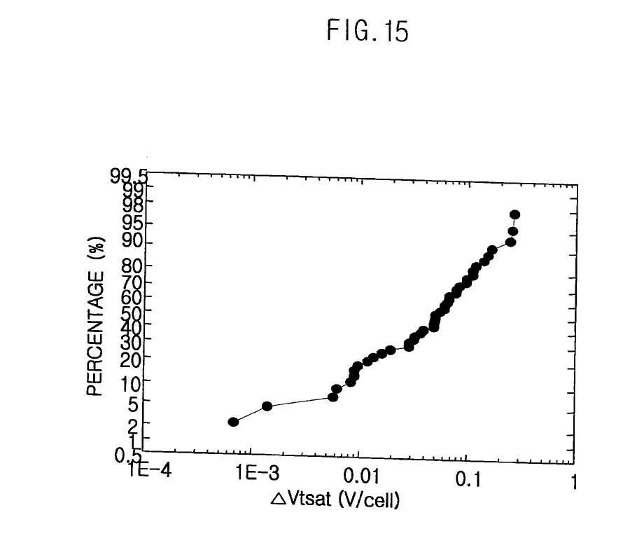

FIG. 15 is a graph showing a distribution of a saturation threshold voltage shift (ΔVtsat) caused by hot electrons injected into a MOSFET in a cell region according to the preferred embodiment of the present invention.

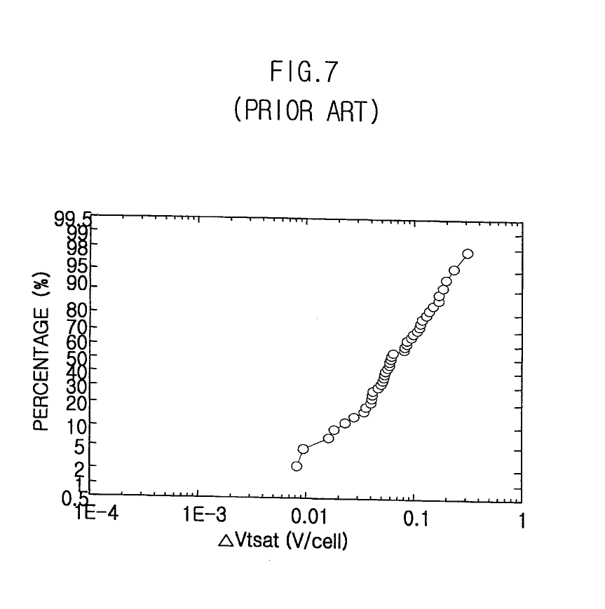

As shown, compared with the distribution of the saturation threshold voltage shift of the conventional MOSFET depicted in FIG. 7, it is verified that the saturation threshold voltage shift is decreased. This decrease indicates the MOSFET is more resistant to degradation of the driving power of the MOSFET caused by the hot electrons. This increased level of the immunity against hot electrons further indicates that the reliability and lifetime of the MOSFET can be improved even when the MOSFET is used for a prolonged period.

According to the preferred embodiment of the present invention, there is a provided effect on an improved dielectric breakdown electric field by preventing the leakage current of the gate insulation layer from being increased. Also, the gate insulation layer has an improved resistance characteristic against the charge stress. This improved resistance results in an increase of the dielectric breakdown charge amount, which provides further effects on the prolonged lifetime and improved reliability of the MOS devices. In addition, it is possible to prevent incidences of degradation and fatigue of the short channel N-type MOSFET caused by hot electrons. Hence, defects in the transistor operation are reduced, resulting in improved lifetime and reliability of semiconductor devices.

Accordingly, on the basis of the above-described effects, it is possible to improve the driving power of devices formed on the substrate and to increase the yield and lifetime of semiconductor devices as the device reliability is improved by controlling the leakage currents. Also, since smaller devices can be easily formed on the substrate, it is possible to fabricate highly integrated semiconductor devices.

While the present invention has been described with respect to certain preferred embodiments, it will be apparent to those skilled in the art that various changes and modifications may be made without departing from the spirit and scope of the invention as defined in the following claims.

What is claimed is:

1. A method for fabricating a semiconductor device, comprising the steps of:
forming a plurality of conductive lines over a wafer wherein a plurality of transistors are to be formed;
securing the wafer to an electrostatic chuck of a plasma chemical vapor deposition (CVD) apparatus; and
depositing an insulation layer filling a gap defined between the conductive lines while cooling the wafer by providing a cooling gas below a bottom surface of the wafer.

2. The method of claim 1, wherein the cooling gas includes an inert gas.

3. The method of claim 2, wherein the inert gas is selected from a group consisting of helium (He), hydrogen (H₂), nitrogen (N₂), argon (Ar) and neon (Ne).

4. The method of claim 2, wherein the inert gas is supplied with an amount ranging from approximately 10 sccm to approximately 200 sccm to cause a pressure at the bottom surface of the wafer to be in a range from approximately 0.1 torr to approximately 50 torr.

5. The method of claim 1, wherein the cooling gas is supplied for a predetermined period prior to performing the plasma CVD process or after performing a sub-step of the plasma CVD process.

6. The method of claim 1, wherein the cooling gas is supplied for a predetermined period after performing the plasma CVD process.

7. The method of claim 1, wherein the wafer is clamped while supplying of the cooling gas below the wafer.

8. The method of claim 7, wherein the clamping of the wafer is carried out by mechanically pressing edges of the wafer.

9. The method of claim 7, wherein the clamping of the wafer is carried out by using static electricity that causes the wafer to be securely attached to the electrostatic chuck.

10. The method of claim 7, wherein the clamping of the wafer is carried out by applying vacuum pumping on a rear surface of the wafer to cause the wafer to be securely attached to the electrostatic chuck.
